(19) United States
(12) Patent Application Publication
(10) Pub. No.: US 2026/0089981 A1
(43) Pub. Date: Mar. 26, 2026

(54) SEMICONDUCTOR STRUCTURE AND METHOD OF MANUFACTURING THE SAME

(71) Applicant: NANYA TECHNOLOGY CORPORATION, New Taipei City (TW)

(72) Inventors: Fang-Hong LEE, New Taipei City (TW); Ji-Feng LIU, New Taipei City (TW)

(21) Appl. No.: 18/896,858

(22) Filed: Sep. 25, 2024

(51) Int. Cl. H10D 1/00; H01L 23/522; H10D 1/68

(52) U.S. Cl. CPC H10D 1/042; H10D 1/043; H10D 1/714; H10D 1/716; H10W 20/496

(57) ABSTRACT

Embodiments of this disclosure provide a semiconductor structure, including an active device layer disposed over a substrate and a capacitor structure disposed on the active device layer. The capacitor structure includes a first conductive layer disposed on the active device layer, an insulating layer disposed on the first conductive layer, a second conductive layer disposed on the insulating layer, a third conductive layer disposed on the second conductive layer, a bottom inner insulating layer surrounding the first conductive layer in a top view, a second inner conductive layer surrounding the bottom inner insulating layer in the top view, and a third inner conductive layer surrounding the second inner conductive layer in the top view. Additionally, a method of manufacturing a semiconductor structure is also disclosed in this disclosure.

### BACKGROUND

### Field of Invention

The present disclosure relates to a semiconductor structure and a method of manufacturing the same.

### Description of Related Art

As electronic devices become lighter and thinner, semiconductor devices, such as dynamic random access memory (DRAM) become more highly integrated. Further, the performance of the DRAM is improved via shortening the pitch between the semiconductor structures in the DRAM. In addition to increasing the difficulty of the manufacturing process, the components in the semiconductor structures are also prone to leakage resulting from too close distances because of shrinking the size of the semiconductor structure.

As a result, in the semiconductor manufacturing process, how to reduce the leakage to improve the process yield of the semiconductor structure has become an important issue.

### SUMMARY

Embodiments of this disclosure provide a method of manufacturing a semiconductor structure, including the following steps. A first supporting layer is formed on an active device layer. An oxide layer is deposited on the first supporting layer, wherein the oxide layer comprises a dopant, and a concentration of the dopant gradually increases from an upper portion of the oxide layer to a lower portion of the oxide layer. A second supporting layer is formed on the oxide layer. The second supporting layer, the oxide layer and the first supporting layer are etched to form a first opening to expose a portion of a top surface of the active device layer.

In some embodiments, the dopant is boron.

In some embodiments, an etching selectivity of the lower portion of the oxide layer is greater than an etching selectivity of the upper portion of the oxide layer.

In some embodiments, a concentration of an etchant of the wet etching process for etching the oxide layer is positively related to the concentration of the dopant in the oxide layer.

In some embodiments, an opening width of the upper portion of the oxide layer is substantially equal to an opening width of the lower portion of the oxide layer.

In some embodiments, the method further includes the following steps. A first conductive layer is formed in the first opening after forming the first opening. The oxide layer is removed to form a second opening to expose a portion of an outer surface of the first conductive layer.

In some embodiments, the method further includes the following steps. An insulating layer is formed on the first conductive layer in the first opening and an inner insulating layer is formed on in the second opening, respectively. A second conductive layer is conformally deposited on the insulating layer and a second inner conductive layer is conformally deposited on the inner insulating layer, respectively. A third conductive layer is formed on the second conductive layer and a third inner conductive layer is formed on the second inner conductive layer, respectively.

Embodiments of this disclosure provide a method of manufacturing a semiconductor structure, including the following steps. A first supporting layer is formed on an active device layer. An oxide layer containing a dopant is deposited on the first supporting layer, wherein an upper portion of the oxide layer has a first doping concentration, a middle portion of the oxide layer has a second doping concentration greater than the first doping concentration, and a lower portion of the oxide layer has a third doping concentration greater than the second doping concentration. A second supporting layer is formed on the oxide layer. The second supporting layer, the oxide layer and the first supporting layer are etched to form a first opening to expose a portion of a top surface of the active device layer.

In some embodiments, etching the second supporting layer, the oxide layer and the first supporting layer comprises a wet etching process.

In some embodiments, a concentration of an etchant for etching the upper portion of the oxide layer is less than a concentration of the etchant for etching the middle portion of the oxide layer, and concentration of the etchant for etching the middle portion of the oxide layer is less than a concentration of the etchant for etching the lower portion of the oxide layer.

In some embodiments, a side surface of the upper portion of the oxide layer exposed by the first opening, a side surface of the middle portion of the oxide layer exposed by the first opening, and a side surface of the lower portion of the oxide layer exposed by the first opening are coplanar after etching.

In some embodiments, the method further includes the following steps. A first conductive layer is conformally deposited in the first opening after forming the first opening. The oxide layer is removed to form a second opening.

In some embodiments, a sidewall of the first conductive layer is substantially perpendicular to a top surface of the active device layer.

In some embodiments, the method further includes the following steps. An insulating layer is formed on the first conductive layer in the first opening and an inner insulating layer is formed in the second opening, respectively. A second conductive layer is conformally deposited on the insulating layer and a second inner conductive layer is conformally deposited on the inner insulating layer, respectively. A third conductive layer is formed on the second conductive layer to fill the first opening and a third inner conductive layer is formed on the second conductive layer to fill the second opening, respectively.

Embodiments of this disclosure provide a semiconductor structure, including an active device layer disposed over a substrate and a capacitor structure disposed on the active device layer. The capacitor structure includes a first conductive layer disposed on the active device layer, an insulating layer disposed on the first conductive layer, a second conductive layer disposed on the insulating layer, a third conductive layer disposed on the second conductive layer, a bottom inner insulating layer surrounding the first conductive layer in a top view, a second inner conductive layer surrounding the bottom inner insulating layer in the top view, and a third inner conductive layer surrounding the second inner conductive layer in the top view.

In some embodiments, the capacitor structure further includes a first dielectric layer disposed on the active device layer and surrounding a bottom portion of the first conductive layer. A side surface of the bottom inner insulating layer contacting the sidewall of the first conductive layer is substantially perpendicular to a top surface of the first dielectric layer.

In some embodiments, the capacitor structure further includes a second dielectric layer disposed on the bottom second inner insulating layer and surrounding a sidewall of the surrounding the first conductive layer. The side surface of the inner insulating layer contacting the sidewall of the first conductive layer is substantially perpendicular to a bottom surface of the second dielectric layer.

In some embodiments, the capacitor structure further includes a top inner insulating layer disposed on the second dielectric layer and surrounding the first conductive layer in the top view, a top second inner conductive layer surrounding the second inner conductive layer in the top view, and top third inner conductive layer surrounding the conductive layer surrounding the top second inner conductive layer in the top view.

In some embodiments, in a cross-section view, the first conductive layer has a width and a height, and a ratio of the height to the width is greater than 30.

In some embodiments, the capacitor structure further includes a third dielectric layer disposed on the top second inner insulating layer and surrounding the sidewall of the surrounding the first conductive layer. A top surface of the third dielectric layer and a top surface of the first conductive layer are coplanar.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. The disclosure can be more fully understood by reading the following detailed description of the embodiment, with reference made to the accompanying drawings as follows.

FIGS. 1 and 2 are cross-section views of a method of manufacturing a semiconductor structure during forming a first opening according to some embodiments of this disclosure,

FIGS. 3-5 are cross-section views of a method of manufacturing a semiconductor structure during forming a capacitor structure according to some embodiments of this disclosure, and

FIG. 6 is a top view based on a cross-section X-X of FIG. 5.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

Further, spatially relative terms, such as “on,” “over,” “under,” “between” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The words “comprise”, “include”, “have”, “contain” and the like used in the present disclosure are open terms, meaning including but not limited to.

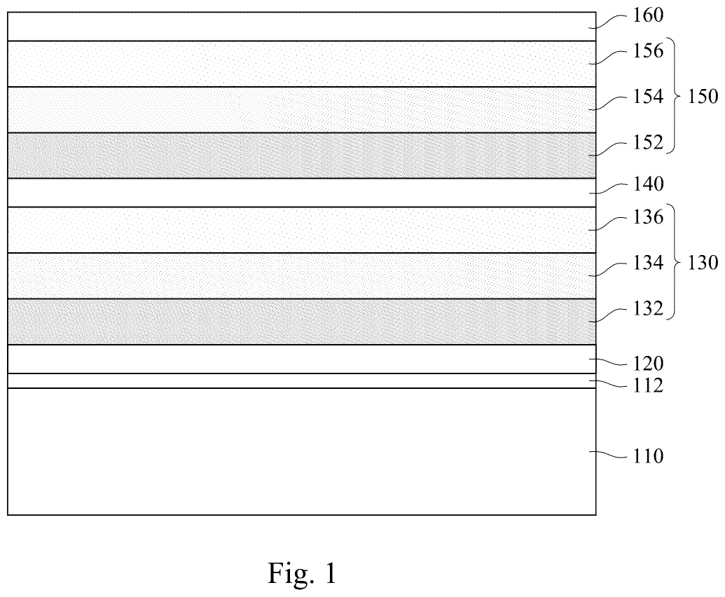

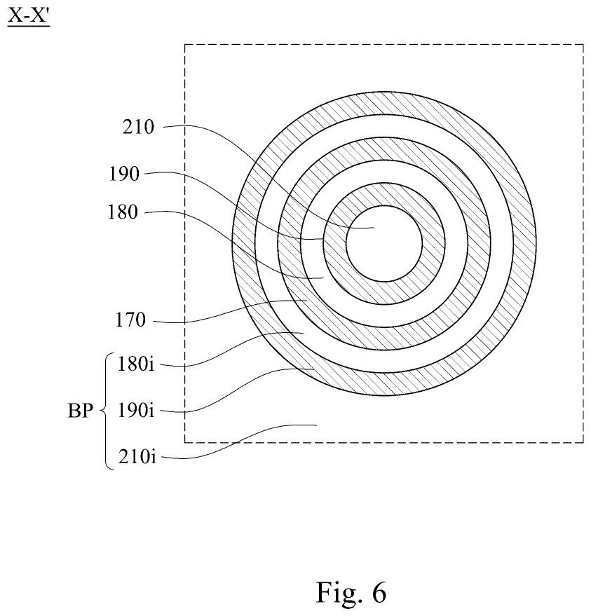

It should be noted that when the following figures, such as FIGS. 1 to 6, are illustrated and described as a series of operations or steps, the description order of these operations or steps should not be limited. For example, some operations or steps may be undertaken in a different order than in the present disclosure, or some operations or steps may occur currently, or some operations may not be used, and/or some operations or steps may be repeated. Moreover, the actual operations or steps of process stages may require additional operations or steps before, during or after forming the semiconductor structure (for example, a semiconductor structure 100 in FIG. 6) to completely form the semiconductor structure 100. Therefore, the present disclosure may briefly illustrate some of these additional operations or steps. Further, unless otherwise stated, the same explanations discussed for the following figures, such as FIGS. 1 to 6, apply directly to the other figures.

As a size of DRAM becomes smaller and smaller, a high aspect ratio contact (HARC) process is used to form a high aspect ratio of a capacitor structure in the related art. However, each of openings for the capacitor structure is formed into a tapered shape after the high aspect ratio contact process. Since there is no enough space to completely fill capacitor materials, especially a bottom portion of the capacitor structure, a capacitance of the capacitor structure becomes worsen. Therefore, embodiments of this disclosure provide a solution to solve the problem.

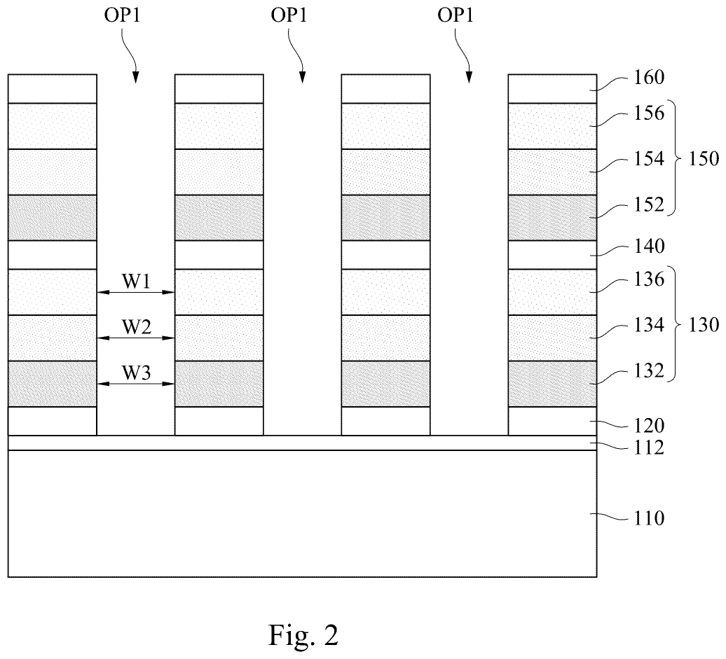

Please refer to FIGS. 1 and 2. FIGS. 1 and 2 are cross-section views of a method of manufacturing a semiconductor structure during forming a first opening according to some embodiments of this disclosure. In FIG. 1, an active device layer 112 disposed on a substrate 110 is provided. In some embodiments, the substrate 110 includes silicon, such as crystalline silicon, polycrystalline silicon, or amorphous silicon. The substrate 110 may include an elemental semiconductor, such as germanium. In some embodiments, the substrate 110 may include alloy semiconductors, such as silicon germanium, silicon germanium carbide, gallium indium phosphide, or other suitable materials. In some embodiments, the substrate 110 may include compound semiconductors, such as silicon carbide (SiC), gallium arsenide (GaAs), indium phosphide (InP), indium arsenide (InAs), or other suitable materials. Moreover, in some embodiments, the substrate 110 may optionally have a semiconductor-on-insulator (SOI) structure. Moreover, the active device layer 112 includes gate structures, word line structures, bit line structures, contact plugs and other active features.

Next, a first supporting layer 120 is formed on the active device layer 112. In some embodiments, the first supporting layer 120 includes a dielectric material, such as nitride. In some embodiments, the first supporting layer 120 includes SiN. In some embodiments, the first supporting layer 120 is formed by a deposition process, such as chemical vapor deposition (CVD). Then, a bottom oxide layer 130 is deposited on the first supporting layer 120. Moreover, the bottom oxide layer 130 includes a dopant, and a concentration of the dopant gradually increases from an upper portion 136 of the bottom oxide layer 130 to a lower portion 132 of the bottom oxide layer 130. In some embodiments, the dopant is boron. As shown in FIG. 1, the bottom oxide layer 130 may substantially include three layers, the upper layer 136, a middle portion 134 and the lower portion 132 of the bottom oxide layer 130. Additionally, the upper portion 136 of the bottom oxide layer 130 has a first doping concentration, the middle portion 134 of the bottom oxide layer 130 has a second doping concentration greater than the first doping concentration, and the lower portion 132 of the bottom oxide layer 132 has a third doping concentration greater than the second doping concentration.

Further, a second supporting layer 140 is formed on the bottom oxide layer 130. In some embodiments, the second supporting layer 140 includes a dielectric material, such as nitride (such as SiN). In some embodiments, the second supporting layer 140 is formed by a deposition process, such as CVD. Then, a top oxide layer 150 is deposited on the second supporting layer 140. Similarly, the top oxide layer 150 includes a dopant, and a concentration of the dopant gradually increases from an upper portion 156 of the top oxide layer 150 to a lower portion 152 of the top oxide layer 150. In some embodiments, the dopant is boron. The upper portion 156 of the top oxide layer 150 has the first doping concentration of the top oxide layer 150, the middle portion 154 of the top oxide layer 150 has the second doping concentration greater than the first doping concentration of the top oxide layer 150, and the lower portion 152 of the top oxide layer 150 has the third doping concentration greater than the second doping concentration of the top oxide layer 150.

Then, a third supporting layer 160 is formed on the top oxide layer 150. In some embodiments, the third supporting layer 160 includes a dielectric material, such as nitride (such as SiN). In some embodiments, the third supporting layer 160 is formed by a deposition process, such as CVD.

Next, in FIG. 2, the third supporting layer 160, the top oxide layer 150, the second supporting layer 140, the bottom oxide layer 130 and the first supporting layer 120 are etched to form a first opening OP1 to expose a portion of a top surface of the active device layer 112. In some embodiments, the third supporting layer 160, the top oxide layer 150, the second supporting layer 140, the bottom oxide layer 130 and the first supporting layer 120 are etched by a wet etching process. Moreover, a concentration of an etchant of the wet etching process for etching the bottom oxide layer 130 and the top oxide layer 150 is positively related to the concentration of the dopant in the bottom oxide layer 130 and the top oxide layer 150. Specifically, taking etching the bottom oxide layer 130 as an example, since the first doping concentration of the upper portion 136 of the bottom oxide layer 130 is less than the second doping concentration of the middle portion 134 of the bottom oxide layer 130, a concentration of the etchant for etching the upper portion 136 of the bottom oxide layer 130 is less than a concentration of the etchant for etching the middle portion 134 of the bottom oxide layer 130. Further, since the second doping concentration of the middle portion 134 of the bottom oxide layer 130 is less than the third doping concentration of the lower portion 132 of the bottom oxide layer 130, a concentration of the etchant for etching the middle portion 134 of the bottom oxide layer 130 is less than a concentration of the etchant for etching the lower portion 132 of the bottom oxide layer 130.

Specifically, through doping the bottom oxide layer 130 with different concentration of the dopant, an etching selectivity of the lower portion 132 of the bottom oxide layer 130 is greater than an etching selectivity of the middle portion 134 of the bottom oxide layer 130, and the etching selectivity of the middle portion 134 of the bottom oxide layer 130 is greater than an etching selectivity of the upper portion 136 of the bottom oxide layer 130. Additionally, an etching mechanism (including a dopant distribution, a etchant distribution and the etching selectivity of the oxide layer based on the dopant distribution) for etching the top oxide layer 150 is also similar to the concentration mechanism for etching the bottom oxide layer 130, which is not repeated again.

Based on the etching mechanism, an opening width W1 of the upper portion 136 of the bottom oxide layer 130 is substantially equal to an opening width W2 of the middle portion 134 of the bottom oxide layer 130, and the opening width W2 of the middle portion 134 of the bottom oxide layer 130 is substantially equal to an opening width W3 of the lower portion 132 of the bottom oxide layer 130. Although not shown in FIG. 2, an opening width of the upper portion 156 of the top oxide layer 150 is substantially equal to an opening width of the middle portion 154 of the top oxide layer 150, and the opening width of the middle portion 154 of the top oxide layer 150 is substantially equal to an opening width of the lower portion 152 of the top oxide layer 150. That is, through the etching mechanism, the first opening OP1 is not tapered in the cross-section view.

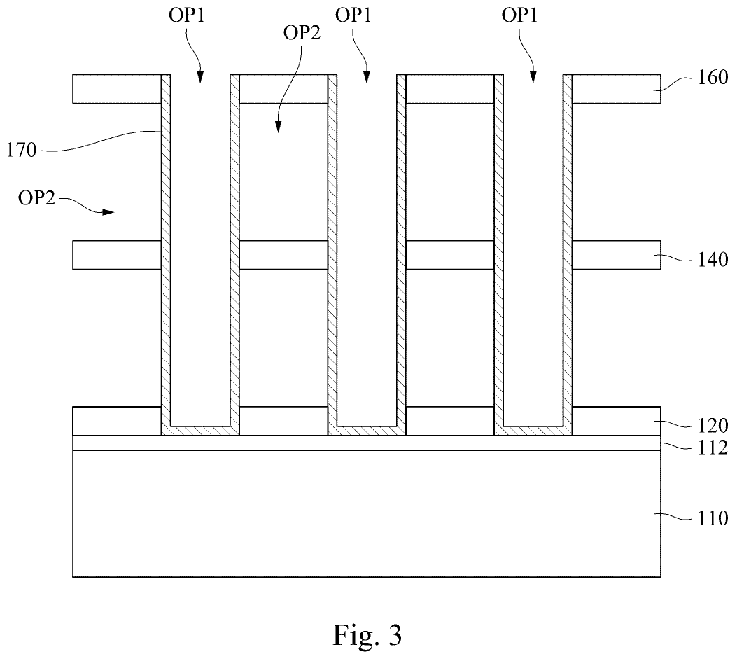

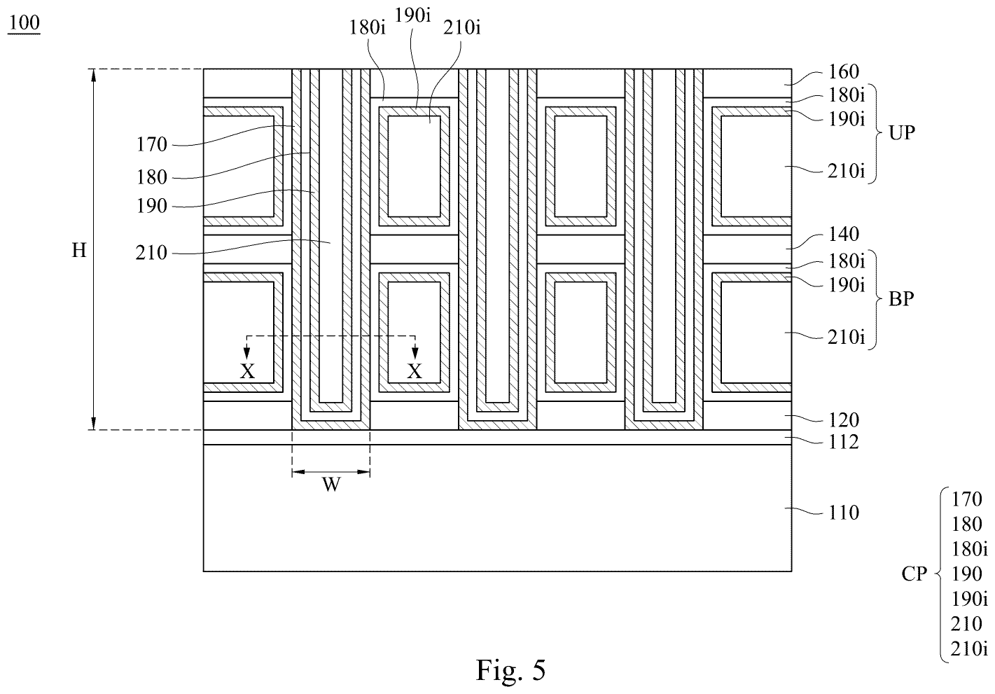

Next, please refer to FIGS. 3-6. FIGS. 3-5 are cross-section views of a method of manufacturing a semiconductor structure during forming a capacitor structure according to some embodiments of this disclosure, and FIG. 6 is a top view based on a cross-section X-X of FIG. 5.

In FIG. 3, a first conductive layer 170 is conformally formed in the first opening OP1 after forming the first opening OP1. Specifically, the first conductive layer 170 is formed on a bottom and a sidewall of the first opening OP1. In some embodiments, the first conductive layer 170 includes TiN. Moreover, a sidewall of the first conductive layer 170 is substantially perpendicular to a top surface of the active device layer 112. Then, the bottom oxide layer 130 (such as in FIG. 2) and the top oxide layer 150 (such as in FIG. 2) are removed to form two second openings OP2 to expose an upper portion and a bottom portion of outer surfaces of the first conductive layer 170. Specifically, one of the two second openings exposes the upper portion of the outer surface of the first conductive layer 170, and the other of the two second openings exposes the bottom portion of the outer surface of the first conductive layer 170. Additionally, the first supporting layer 120, the second supporting layer 140 and the third supporting layer 160 still surround the first conductive layer 170 after forming the two second openings OP2, so that a structure of the first conductive layer 170 and the first opening OP1 may not collapse and may be still maintained. In some embodiments, the bottom oxide layer 130 (such as in FIG. 2) and the top oxide layer 150 (such as in FIG. 2) are removed by an etching process.

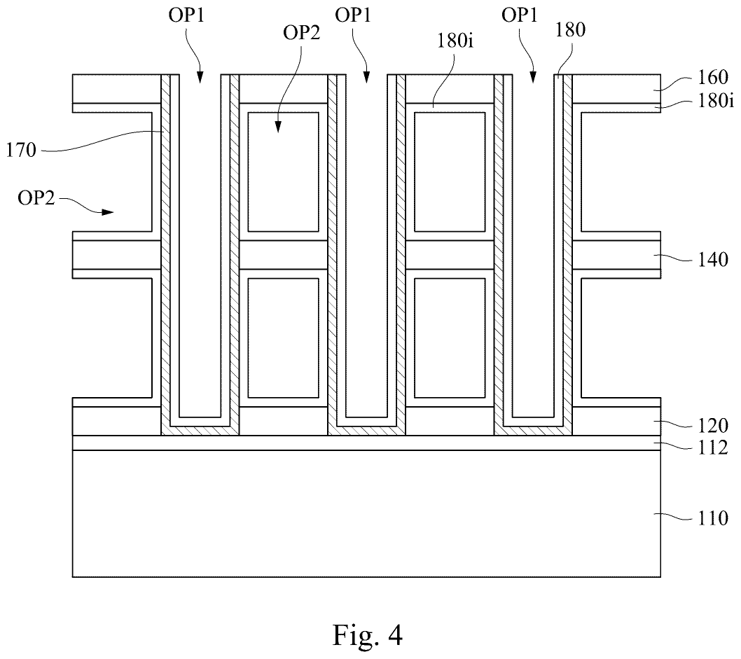

Next, in FIG. 4, an insulating layer 180 is conformally deposited on the first opening OP1, and an inner insulating layer 180i is conformally deposited on the outer surface of the first conductive layer 170 in each of the two second opening. Specifically, the inner insulating layer 180i is conformally deposited on the upper portion of the outer surface of the first conductive layer 170, a bottom surface of the third supporting layer 160 and a top surface of the second supporting layer 140 exposed by one of the two second openings OP2, and the inner insulating layer 180i is also conformally deposited on the bottom portion of the outer surface of the first conductive layer 170, a bottom surface of the second supporting layer 140 and a top surface of the first supporting layer 120 exposed by the other of the two second openings OP2. In some embodiments, the insulating layer 180 and the inner insulating layer 180i include a high-K material, such as a K value higher than a K value of silicon dioxide.

Further, in FIG. 5, after forming the insulating layer 180 and the inner insulating layer 180i, a second conductive layer 190 is conformally formed on the insulating layer 180 in the first opening OP1 (such as in FIG. 4), and a second inner conductive layer 190i is conformally formed on the insulating layer 180 in each of the two second openings OP2 (such as in FIG. 4). In some embodiments, the second conductive layer 190 and the second inner conductive layer 190i include TiN.

Next, a third conductive layer 210 is formed on the second conductive layer to fill the first opening OP1 (such as in FIG. 4), and a third inner conductive layer 210i is formed on the second inner conductive layer 190i to fill each of the two second openings OP2 (such as in FIG. 4). In some embodiments, the third conductive layer 210 and the third inner conductive layer 210i include polysilicon. Additionally, please refer to a top view of FIG. 6, taking a center of a capacitor structure CP as an inner side, the capacitor structure CP includes the third inner conductive layer 210i, the second inner conductive layer 190i, the inner insulating layer 180i, the first conductive layer 170, the insulating layer 180, the second conductive layer 190 and the third conductive layer 210 from an outer side to the inner side after forming the third conductive layer 210 and the third inner conductive layer 210i. Although FIG. 6 illustrates a bottom portion BP of the capacitor structure CP and an upper portion UP of the capacitor structure CP is not shown in FIG. 6, the upper portion UP of the capacitor structure CP includes each of the layers described above similar to the bottom portion BP of the capacitor structure CP. It is worth to mention that since the first opening OP1 (such as in FIG. 2) formed through the above etching mechanism, the number of the various layers formed in the bottom portion BP of the capacitor structure CP is equal to the number of the various layers formed in the upper portion UP of the capacitor structure CP.

The method of manufacturing the capacitor structure CP provided by the embodiments of this disclosure may produce the capacitor structure CP with a relatively straight profile (for example, the sidewall of the first conductive layer 170 is perpendicular to the top surface of the active device layer 112 in the cross-section) without producing a tapered profile. In this way, the method of manufacturing the capacitor structure CP provided by the embodiments of this disclosure can improve a capacitance and a leakage performance of the capacitor structure CP.

Embodiments of this disclosure also provide a semiconductor structure as shown in FIGS. 5 and 6. The semiconductor structure 100 includes an active device layer disposed over a substrate 110 and a capacitor structure CP disposed on the active device layer 112. The capacitor structure CP includes a third conductive layer 210, a second conductive layer 190 surrounding the third conductive layer 210, an insulating layer 180 surrounding the second conductive layer 190 and a first conductive layer 170 surrounding the insulating layer 180. The capacitor structure CP further includes a first dielectric layer 120 on the active device layer 112 and surrounding a bottom portion of the first conductive layer 170. In some embodiments, the first conductive layer 170 has a width W and a height H, and an aspect ratio of the capacitor structure CP (a ratio of the height H to the width W (H/W)) is greater than 30.

Further, the capacitor structure CP may be defined a bottom portion BP and an upper portion UP based on a second dielectric layer 140 (described later). In the top view of FIG. 6, the bottom portion BP of the capacitor structure CP includes an inner insulating layer 180i (also called as a bottom inner insulating layer 180i) surrounding the first conductive layer 170, a second inner conductive layer 190i (also called as a bottom second inner conductive layer 190i) surrounding the bottom inner insulating layer 180i, and a third inner conductive layer 210i (also called as a bottom third inner conductive layer 210i) surrounding the bottom second inner conductive layer 190i. In some embodiments, a bottom surface of the bottom inner insulating layer 180i directly contacts a top surface of the first dielectric layer 120, as shown in FIG. 5. In some embodiments, a side surface of the bottom inner insulating layer 180i contacting the sidewall of the first conductive layer 170 is substantially perpendicular to the top surface of the first dielectric layer 120.

In FIG. 5, the capacitor structure CP further includes the second dielectric layer 140 on the bottom inner insulating layer 180i and surrounding a middle portion of the sidewall of the first conductive layer 170. In some embodiments, the side surface of the inner insulating layer 180i contacting the sidewall of the first conductive layer 170 is substantially perpendicular to a bottom surface of the second dielectric layer. In some embodiments, a top surface of the top inner insulating layer 180i contacts a bottom surface of the second dielectric layer 140, as shown in FIG. 5.

Additionally, in the top view, an upper portion UP of the capacitor structure CP includes an inner insulating layer 180i (also called as a top inner insulating layer 180i) on the second dielectric layer 140 and surrounding the first conductive layer 170, a second inner conductive layer 190i (also called as a top second inner conductive layer 190i) surrounding the bottom inner insulating layer 180i, and a third inner conductive layer 210i (also called as a top third inner conductive layer 210i surrounding the bottom second inner conductive layer 190i. In some embodiments, a bottom surface of the top inner insulating layer 180i contacts a top surface of the second dielectric layer 140, as shown in FIG. 5. In some embodiments, the side surface of the inner insulating layer 180i contacting the sidewall of the first conductive layer 170 is substantially perpendicular to a bottom surface of the second dielectric layer 140.

In FIG. 5, the capacitor structure CP further includes a third dielectric layer on the top inner insulating layer 180i and surrounding an upper portion of the sidewall of the first conductive layer 170. In some embodiments, a top surface of the top inner insulating layer 180i contacts a bottom surface of the third dielectric layer 160. In some embodiments, the side surface of the top inner insulating layer 180i contacting the sidewall of the first conductive layer 170 is substantially perpendicular to the bottom surface of the third dielectric layer 160. In some embodiments, top surfaces of the third dielectric layer 160, the first conductive layer 170, the insulating layer 180, the second conductive layer 190 and the third conductive layer 210 are coplanar.

As stated as above, the capacitor structure CP provided by the embodiments of this disclosure has a high aspect ratio contact (HARC) without the tapered profile. Thus, the capacitance and the leakage performance of the capacitor structure CP may be improved due to a straight critical dimension (CD) of the HARC.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing a semiconductor structure, comprising:
forming a first supporting layer on an active device layer;
depositing an oxide layer on the first supporting layer, wherein the oxide layer comprises a dopant, and a concentration of the dopant gradually increases from an upper portion of the oxide layer to a lower portion of the oxide layer;
forming a second supporting layer on the oxide layer; and
etching the second supporting layer, the oxide layer and the first supporting layer to form a first opening to expose a portion of a top surface of the active device layer.

2. The method of claim 1, wherein the dopant is boron.

3. The method of claim 1, wherein an etching selectivity of the lower portion of the oxide layer is greater than an etching selectivity of the upper portion of the oxide layer.

4. The method of claim 3, wherein a concentration of an etchant for etching the oxide layer is positively related to the concentration of the dopant in the oxide layer.

5. The method of claim 1, wherein an opening width of the upper portion of the oxide layer is substantially equal to an opening width of the lower portion of the oxide layer.

6. The method of claim 1, further comprising:
depositing a first conductive layer in the first opening after forming the first opening; and
removing the oxide layer to form a second opening to expose a portion of an outer surface of the first conductive layer.

7. The method of claim 6, further comprising:
forming an insulating layer on the first conductive layer in the first opening and an inner insulating layer in the second opening, respectively;
conformally depositing a second conductive layer on the insulating layer and a second inner conductive layer on the inner insulating layer, respectively; and
forming a third conductive layer on the second conductive layer and a third inner conductive layer on the second inner conductive layer, respectively.

8. A method of manufacturing a semiconductor structure, comprising:
forming a first supporting layer on an active device layer;
depositing an oxide layer containing a dopant on the first supporting layer, wherein an upper portion of the oxide layer has a first doping concentration, a middle portion of the oxide layer has a second doping concentration greater than the first doping concentration, and a lower portion of the oxide layer has a third doping concentration greater than the second doping concentration;
forming a second supporting layer on the oxide layer; and
etching the second supporting layer, the oxide layer and the first supporting layer to form a first opening to expose a portion of a top surface of the active device layer.

9. The method of claim 8, wherein etching the second supporting layer, the oxide layer and the first supporting layer comprises a wet etching process.

10. The method of claim 8, wherein a concentration of an etchant for etching the upper portion of the oxide layer is less than a concentration of the etchant for etching the middle portion of the oxide layer, and concentration of the etchant for etching the middle portion of the oxide layer is less than a concentration of the etchant for etching the lower portion of the oxide layer.

11. The method of claim 8, wherein a side surface of the upper portion of the oxide layer exposed by the first opening, a side surface of the middle portion of the oxide layer exposed by the first opening, and a side surface of the lower portion of the oxide layer exposed by the first opening are coplanar after etching.

12. The method of claim 8, further comprising:
conformally depositing a first conductive layer in the first opening after forming the first opening; and
removing the oxide layer to form a second opening.

13. The method of claim 12, wherein a sidewall of the first conductive layer is substantially perpendicular to a top surface of the active device layer.

14. The method of claim 12, further comprising:
forming an insulating layer on the first conductive layer in the first opening and an inner insulating layer in the second opening, respectively;
conformally depositing a second conductive layer on the insulating layer and a second inner conductive layer on the inner insulating layer, respectively; and
forming a third conductive layer on the second conductive layer to fill the first opening and a third inner conductive layer on the second conductive layer to fill the second opening, respectively.

15. A semiconductor structure, comprising:
an active device layer disposed over a substrate; and
a capacitor structure disposed on the active device layer, wherein the capacitor structure comprises:
a first conductive layer disposed on the active device layer;
an insulating layer disposed on the first conductive layer;
a second conductive layer disposed on the insulating layer;
a third conductive layer disposed on the second conductive layer;
a bottom inner insulating layer surrounding the first conductive layer in a top view;
a second inner conductive layer surrounding the bottom inner insulating layer in the top view; and
a third inner conductive layer surrounding the second inner conductive layer in the top view.

16. The semiconductor structure of claim 15, wherein the capacitor structure further comprises:
a first dielectric layer disposed on the active device layer and surrounding a bottom portion of the first conductive layer,
wherein a side surface of the bottom inner insulating layer contacting a sidewall of the first conductive layer is substantially perpendicular to a top surface of the first dielectric layer.

17. The semiconductor structure of claim 16, wherein the capacitor structure further comprises:
a second dielectric layer disposed on the bottom inner insulating layer and surrounding a sidewall of the first conductive layer,
wherein the side surface of the bottom inner insulating layer contacting the sidewall of the first conductive layer is substantially perpendicular to a bottom surface of the second dielectric layer.

18. The semiconductor structure of claim 17, wherein the capacitor structure further comprises:
a top inner insulating layer disposed on the second dielectric layer and surrounding the first conductive layer in the top view;
a top second inner conductive layer surrounding the top second inner conductive layer in the top view; and
a top third inner conductive layer surrounding the top second inner conductive layer in the top view.

19. The semiconductor structure of claim 18, wherein in a cross-section view, the first conductive layer has a height and a width, and a ratio of the height to the width is greater than 30.

20. The semiconductor structure of claim 18, wherein the capacitor structure further comprises:
a third dielectric layer disposed on the top second inner insulating layer and surrounding the sidewall of the first conductive layer,
wherein a top surface of the third dielectric layer and a top surface of the first conductive layer are coplanar.
